(19) United States
(12) Patent Application Publication
(10) Pub. No.: US 2009/0067148 A1
(43) Pub. Date: Mar. 12, 2009

(54) PORTABLE ELECTRONIC DEVICE WITH DETACHABLE RECEIVER

(75) Inventor: YU-YUAN LIN, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 11/964,834

(22) Filed: Dec. 27, 2007

(30) Foreign Application Priority Data
Sep. 11, 2007 (CN) 200710201658.9

(51) Int. Cl. H05K 5/02

(52) U.S. Cl. 361/807

(57) ABSTRACT

A portable electronic device (100) includes a main body (10), a detachable member (30), a latching module (60), and a button (40). The detachable member is assembled to the main body by engagement of the latching module and the button. The button moves in a first direction to control the latching module to move in a second direction.

### BACKGROUND OF THE INVENTION

1. Field of the Invention

The present invention generally relates to portable electronic devices, and particularly to a portable electronic device having a detachable module such as a detachable receiver.

2. Description of Related Art

With the development of wireless communication and information processing technologies, portable electronic devices, such as mobile telephones and personal digital assistants (PDAs), are now in widespread use. These portable electronic devices enable consumers to enjoy high technology services, almost anytime and anywhere.

Such portable electronic device generally includes a receiver formed at one end thereof. The receiver is used for converting electrical signals from a phone call into sounds and for playing music stored in a MP3 (i.e., Moving Picture Experts Group Audio Layer III, MPEG AudioLayer-3) module. When listening to the call, the end having the receiver of the portable electronic device is placed near a user's ear. While playing music, the user may place the portable electronic device in a hand, in a bag, or on a desk. Alternatively, the user can listen to the call or music by an external earphone. The earphone may be wirelessly connected to the portable electronic device by bluetooth technology or may be connected to the portable electronic device by a wire. However, the wire of the earphone tends to tangles with other surrounding objects and the wireless earphone is often lost due to its small volume.

Therefore, a new portable electronic device is desired in order to overcome the above-described problems.

### SUMMARY

In one aspect thereof, a portable electronic device includes a main body, a detachable member, a latching module, and a button. The detachable member is assembled to the main body by engagement of the latching module and the button. The button is configured for moving in a first direction to control the latching module to move in a second direction.

Other advantages and novel features of the embodiments will become more apparent from the following detailed description thereof, when taken in conjunction with the accompanying drawings.

### BRIEF DESCRIPTION OF THE DRAWINGS

Many aspects of the present portable electronic device can be better understood with reference to the following drawings. The components in the drawings are not necessarily drawn to scale, the emphasis instead being placed upon clearly illustrating the principles of the present portable electronic device and its potential applications. Moreover, in the drawings, like reference numerals designate corresponding parts throughout the several views, in which:

FIG. 1 is an assembled, isometric view of a portable electronic device, in accordance with a first embodiment;

FIG. 2 is an exploded, partially cut-away, isometric view of the portable electronic device shown in FIG. 1;

FIG. 3 is similar to FIG. 2, but viewed from another aspect;

FIG. 4 is an assembled, partially cut-away, isometric view of the upper housing, the receiver, and the button of the portable electronic device shown in FIG. 3;

FIG. 5 is a cross-sectional view of the portable electronic device along line V-V of FIG. 1;

FIG. 6 is similar to FIG. 5, but showing the button is compressed and the receiver is released;

FIG. 7 is a partially assembled, isometric view of the portable electronic device shown in FIG. 2; and

FIG. 8 is an isometric view of a portable electronic device, in accordance with a second embodiment.

### DETAILED DESCRIPTION OF THE EMBODIMENTS

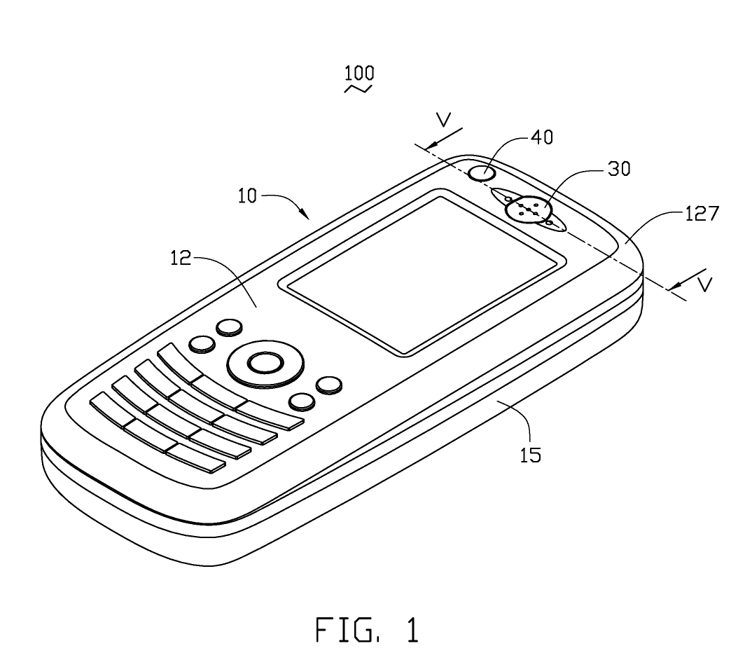

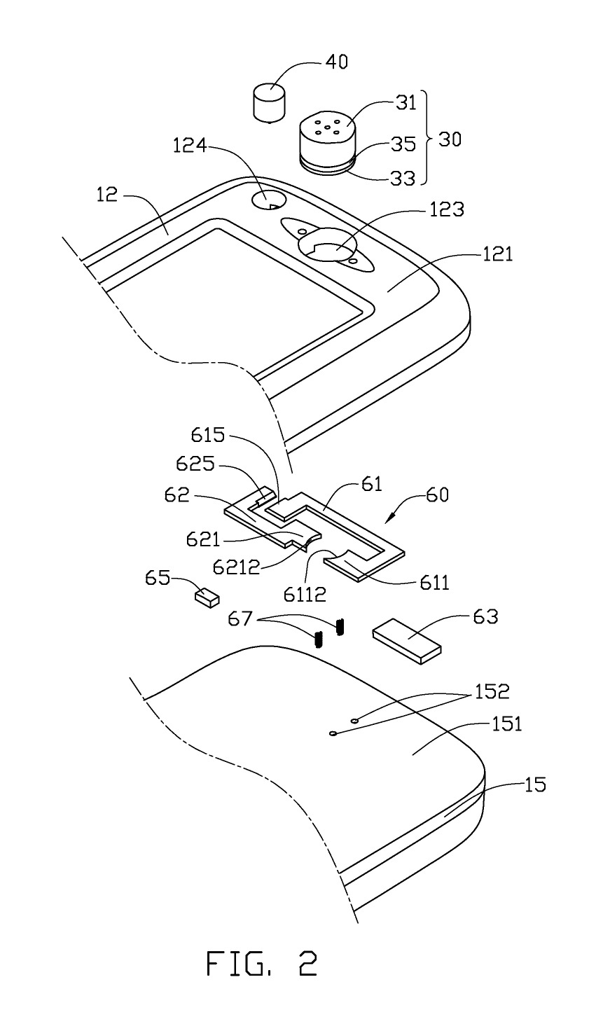

Referring to the drawings in detail, FIG. 1 shows a portable electronic device 100 in accordance with a first embodiment. In the present embodiment, the portable electronic device 100 is a mobile phone. Also referring to FIG. 2, the portable electronic device 100 includes a main body 10, a receiver 30, a button 40 located adjacent to the receiver 30, and a latching module 60. The receiver 30 is detachably received in the main body 10 by the button 40 and the latching module 60.

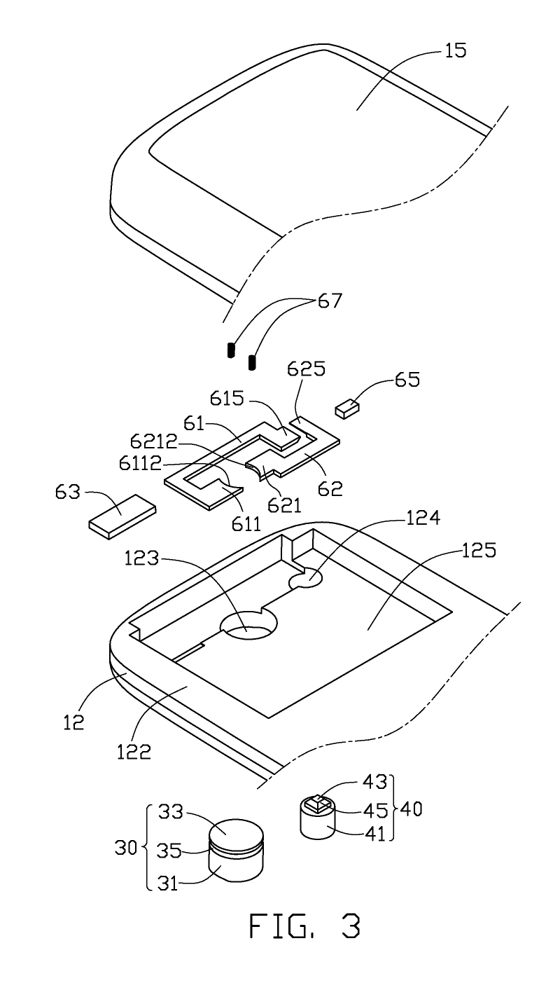

Also referring to FIG. 3, the main body 10 includes an upper housing 12 and a lower housing 15 fixed to the upper housing 12. The upper housing 12 has an outer surface 121 and an inner surface 122 on the opposite side of the outer surface 121. The upper housing 12 has one end defining a receiver recess 123 and a button recess 124 in the outer surface 121, and a receiving cavity 125 in the inner surface 122. The receiver recess 123 and the button recess 124 respectively communicate with the receiving cavity 125. The lower housing 15 has a mounting surface 151. The upper housing 12 is configured for being fixed to the mounting surface 151 of the lower housing 15. The lower housing 15 defines two mounting grooves 152 in the mounting surface 151 at one end thereof.

The receiver 30 is configured (i.e., structured and arranged) for converting electrical signals from a phone call into sounds. The receiver 30 is cylindrical in shape and is configured for being receivable in the receiver recess 123 of the upper housing 12. The receiver 30 has an outer end 31 and an inner end 33 on the opposite side of the outer end 31. The outer end 31 defines a plurality of holes configured for allowing sounds to travel therethrough. The inner end 33 defines an annular slot 35 in a periphery thereof.

The button 40 is configured for being receivable in the button recess 124 of the upper housing 12. The button 40 has a cylindrical button body 41 and a driving portion 43 formed at an end of the button body 41. The driving portion 43 is a substantially pyramid in shape and has four slanting sides 45. Each slanting side 45 is a substantially trapezium in shape.

The latching module 60 includes a first latching member 61, a second latching member 62, a first elastic member 63, a second elastic member 65, and two auxiliary elastic members 67. The first latching member 61, the second latching member 62, the first elastic member 63, and the second elastic member 65 are configured for being receivable in the receiving cavity 125 of upper housing 12. The first latching member 61 is substantially U-shaped, and has a first latching portion 611 and a first wedge 615 extending respectively particularly from two distal ends and toward to a same direction. The first latching portion 611 has a first arched recessed distal surface 6112 configured for being receivable in the slot 35 of the receiver 30. The first wedge 615 is configured for engaging with a corresponding slanting side 45 of the button 40.

The second latching member 62 is substantially U-shaped. The second latching member 62 has a second latching portion 621 and a second wedge 625 respectively formed at two ends thereof. The second latching portion 621 has a second arched recessed distal surface 6212 configured for being receivable in the slot 35 of the receiver 30. The second wedge 625 is configured for engaging with a corresponding slanting side 45 of the button 40. The first elastic member 63 and the second elastic member 65 are rectangular boards in shape. Each auxiliary elastic member 67 is a helical spring configured for being receivable in a corresponding mounting groove 152 of the lower housing 15. A height of each auxiliary elastic member 67 is higher than a depth of each mounting groove 152 so that when each auxiliary elastic member 67 is received in the corresponding mounting groove 152, one end of each auxiliary elastic member 67 is exposed outwardly.

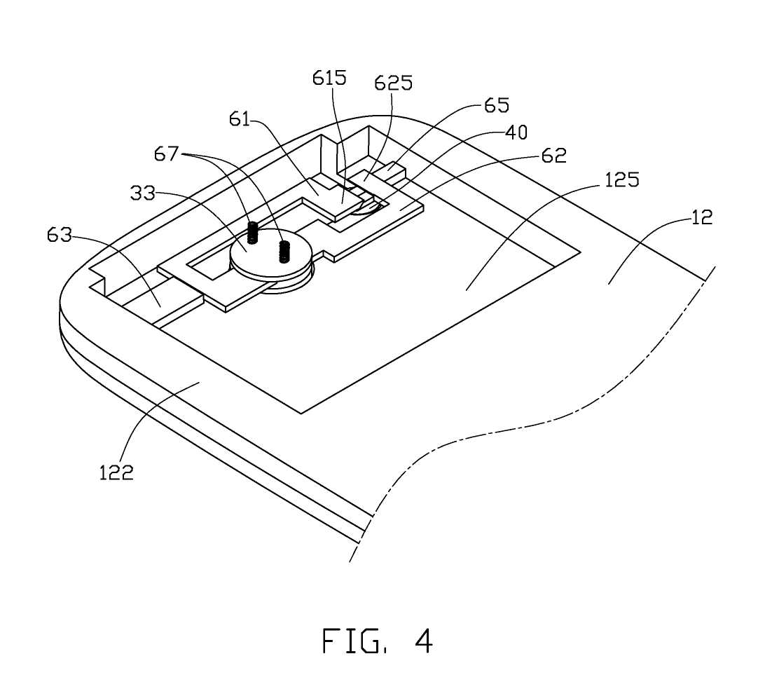

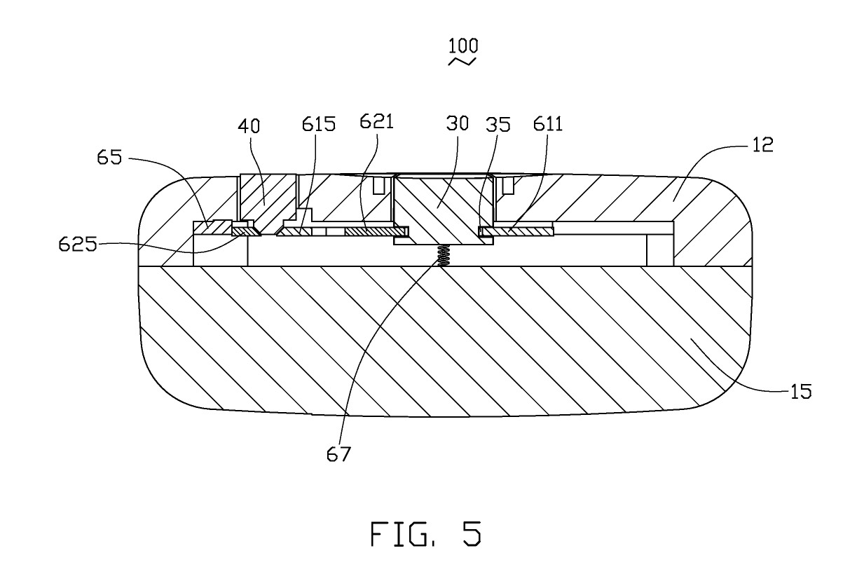

In assembly, the receiver 30 is inserted into the receiver recess 123 of the upper housing 12 with the outer end 31 exposing outwardly. The button 40 is inserted into the button recess 124 of the upper housing 12 with the button body 41 exposing outwardly. The first latching member 61 and the second latching member 62 are inserted into the receiving cavity 125 of the upper housing 12. The first latching portion 611 faces the second latching portion 621. The first distal surface 6112 and the second distal surface 6212 are both received in the slot 35 of the receiver 30. The first wedge 615 faces the second wedge 625. The first wedge 615 and the second wedge 625 respectively correspond with two opposing slanting sides 45 of the button 40. The first elastic member 63 is located between the first latching member 61 and the upper housing 12, and in the receiving cavity 125. The second elastic member 65 is located between the second latching member 62 and the upper housing 12, and in the receiving cavity 125. The receiver 30 and the button 40 are mounted to the upper housing 12 by the latching module 60, as shown in FIG. 4. The upper housing 12 is fixed to the mounting surface 151 of the lower housing 15 with one end of each auxiliary elastic member 67 being inserted into a corresponding mounting groove 152 of the lower housing 15. The inner end 33 of the receiver 30 resists the two other ends of the auxiliary elastic members 67 and the auxiliary elastic members 67 are compressed. The portable electronic device 100 is completely assembled as represented in FIGS. 1 and 5.

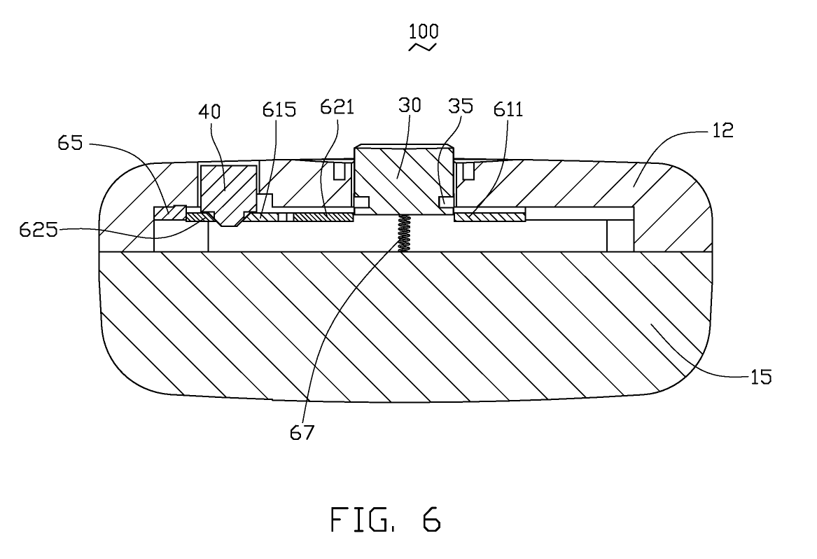

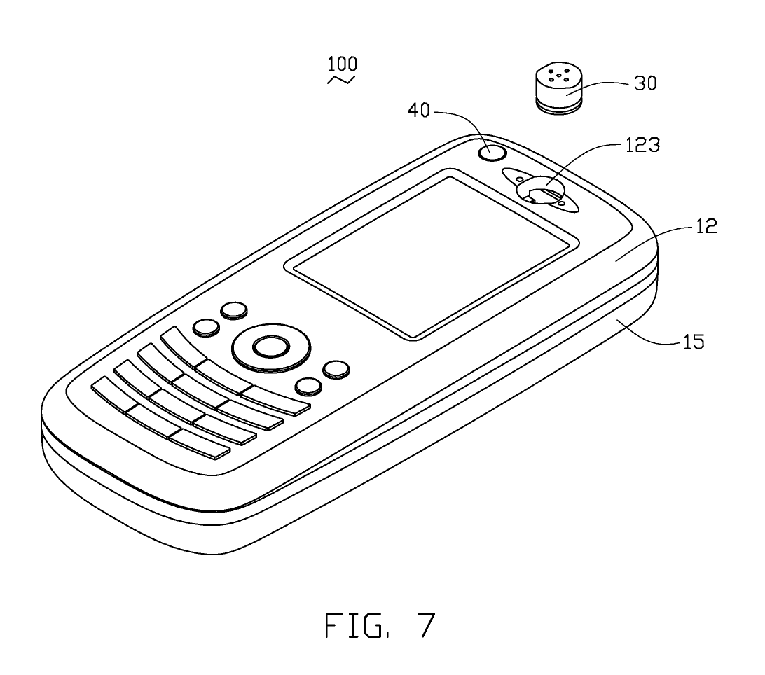

Also referring to FIG. 6, in use, when the user wants to detach the receiver 30 from the main body 10, the button 40 is pressed in a downward direction. The first latching member 61 and the second latching member 62 are moved away from each other in a horizontal direction due to the engagement between the first wedge 615 and a corresponding slanting side 45, and the engagement between the second wedge 625 and a corresponding slanting sides 45. Correspondingly, the first latching portion 611 and the second latching portion 621 are moved away from the slot 35 of the receiver 30. The first elastic member 63 and the second elastic member 65 are respectively compressed. The receiver 30 is released from the first latching portion 611 and the second latching portion 621 and is pushed upwardly due to decompression of the compressed auxiliary elastic members 67. Thus, the receiver 30 is released from the latching module 60, as represented in FIG. 7 and the user can insert the receiver 30 into an ear of the user. The button 40 is released, and the first latching portion 611 and the second latching portion 621 return to resist the receiver 30 due to decompression of the compressed first elastic member 63 and the second elastic member 65.

When assembling the receiver 30 to the main body 10, the button 40 is pressed downwardly. The first latching portion 611 and the second latching portion 621 are moved away in the horizontal direction from each other due to the engagements between the first wedge 615, the second wedge 625 and the slanting sides 45. The first elastic member 63 and the second elastic member 65 are compressed. The receiver 30 is placed downwardly to compress the auxiliary elastic members 67. The button 40 is released, and the first latching portion 611 and the second latching portion 621 are moved into the slot 35 of the receiver 30 respectively due to decompression of the compressed first elastic member 63 and the second elastic member 65.

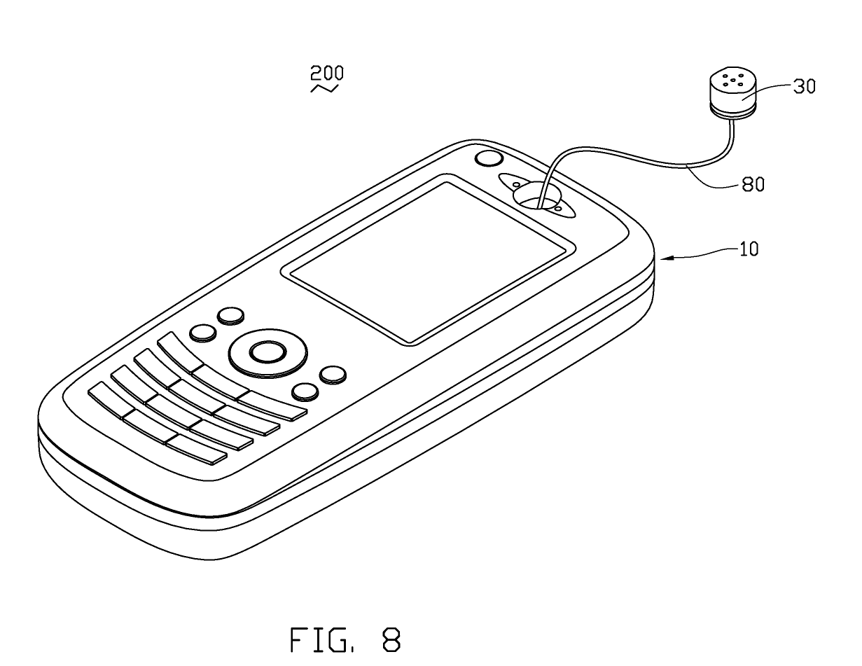

Also referring to FIG. 8, a portable electronic device 200 in accordance with a second embodiment is shown. The portable electronic device 200 is similar to the portable electronic device 100 of the first embodiment except that the receiver 30 of the portable electronic device 200 is further connected to the main body 10 by a line 80. The line 80 is flexibly received in the main body 10.

It should be understood that the receiver 30 may be other detachable members such as a microphone. The second latching member 62 may be omitted and only the first latching member 61 is used to latch the receiver 30. The first elastic member 63 and the second elastic member 65 may have an alternative shape such as a cylinder or a helical spring.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A portable electronic device, comprising:
a main body;
a detachable member;
a latching module, the detachable member being assembled to the main body by the latching module; and
a button configured for moving in a first direction to control the latching module to move in a second direction.

2. The portable electronic device as claimed in claim 1, wherein the latching module includes a first latching member, the first latching member having a first wedge formed at one end thereof, and the first wedge being configured for engaging with the button to hold or release the detachable member.

3. The portable electronic device as claimed in claim 2, wherein the button has a driving portion formed at one end thereof, the driving portion having a slanting side, the slanting side being configured for engaging with the first wedge of the first latching member, and wherein a first movement of the button in the first direction resulting in a second movement of the first latching member in the second direction perpendicular to the first direction.

4. The portable electronic device as claimed in claim 2, wherein the first latching member has a first latching portion formed thereon, the first latching portion having an arched recessed distal surface, the detachable member defining a slot at one end thereof, and the distal surface being configured for being receivable in the slot.

5. The portable electronic device as claimed in claim 2, wherein the first latching member is made of elastic material.

6. The portable electronic device as claimed in claim 2, wherein the first latching member is substantially U-shaped.

7. A portable electronic device, comprising:
a main body;
a receiver;
a latching module, the receiver being detachably assembled to the main body by the latching module; and
a button configured for controlling the latching module to hold or release the receiver.

8. The portable electronic device as claimed in claim 7, wherein the latching module includes a first latching member, the first latching member having a first wedge formed at one end thereof, and the first wedge being configured for engaging with the button to hold or release the receiver.

9. The portable electronic device as claimed in claim 8, wherein the button has a driving portion formed at one end thereof, the driving portion having a slanting side configured for engaging with the first wedge of the first latching member, and a first movement of the button in a first direction resulting in a second movement of the first latching member in a second direction.

10. The portable electronic device as claimed in claim 9, wherein the first direction is perpendicular to the second direction.

11. The portable electronic device as claimed in claim 8, wherein the first latching member has a first latching portion formed thereon, the first latching portion having an arched recessed distal surface, and the distal surface being configured for resisting the receiver.

12. The portable electronic device as claimed in claim 11, wherein the receiver defines a slot at one end thereof, and the first latching member being configured for being receivable in the slot.

13. The portable electronic device as claimed in claim 11, wherein the first latching member is made of elastic material.

14. The portable electronic device as claimed in claim 11, wherein the first latching member is substantially U-shaped.

15. The portable electronic device as claimed in claim 11, wherein the latching module further includes a first elastic member, the first elastic member being mounted to the main body by the first latching member, and the first elastic member being configured for providing a force to move the first latching member.

16. The portable electronic device as claimed in claim 11, wherein the latching module further includes a second latching member, the second latching member having a second wedge formed at one end thereof, the driving portion of the button having a second slanting side, and the second slanting side being configured for engaging with the second wedge.

17. The portable electronic device as claimed in claim 7, wherein the latching module is connected to the main body by a flexible line.

18. The portable electronic device as claimed in claim 7, wherein the main body includes an upper housing, the upper housing having an outer surface and an inner surface opposing to the outer surface, the upper housing defining a receiver recess for receiving the receiver and a button recess for receiving the button through the outer surface, and defining a receiving cavity for receiving the latching module through the inner surface, and the receiver recess and the button recess respectively communicating with the receiving cavity.

19. The portable electronic device as claimed in claim 18, wherein the main body includes a lower housing, the lower housing having a mounting surface, the upper housing being fixed on the mounting surface, the latching module further including an auxiliary elastic member, and the auxiliary elastic member being mounted between the receiver and the mounting surface.
